(19) United States
(12) Patent Application Publication
(10) Pub. No.: US 2017/0287935 A1
(43) Pub. Date: Oct. 5, 2017

(54) VARIABLE BURIED OXIDE THICKNESS FOR SILICON-ON-INSULATOR DEVICES

(71) Applicant: SKYWORKS SOLUTIONS, INC., Woburn, MA (US)

(72) Inventors: Jerod F. MASON, Bedford, MA (US); David Scott WHITEFIELD, Andover, MA (US); Hailing WANG, Acton, MA (US); Hanching FUH, Allston, MA (US)

(21) Appl. No.: 15/476,248

(22) Filed: Mar. 31, 2017

Related U.S. Application Data
(60) Provisional application No. 62/316,522, filed on Mar. 31, 2016.
(60) Provisional application No. 62/316,523, filed on Mar. 31, 2016.
(60) Provisional application No. 62/316,524, filed on Mar. 31, 2016.

(51) Int. Cl. H01L 27/12; H01L 23/66; H01L 23/538; H01L 29/06; H01L 21/84

(52) U.S. Cl. CPC H01L 27/1203; H01L 29/0649; H01L 21/84; H01L 23/538; H01L 23/66; H01L 27/0688

(57) ABSTRACT

Variable buried oxide thickness for silicon-on-insulator devices. In some embodiments, a radio-frequency device can include a silicon-on-insulator substrate having an insulator layer and a handle wafer. The radio-frequency device can further include a plurality of field-effect transistors implemented over the insulator layer. Each transistor can be separated from the handle wafer by a corresponding portion of the insulator layer. The corresponding portion of the insulator layer can have an average thickness value such that the average thickness values associated with the plurality of FETs transistors form a non-uniform distribution.

### CROSS-REFERENCE TO RELATED APPLICATION(S)

This application claims priority to U.S. Provisional Application Nos. 62/316,522 filed Mar. 31, 2016, entitled VARIABLE BURIED OXIDE FOR SILICON-ON INSULATOR DEVICES, 62/316,523 filed Mar. 31, 2016, entitled VARIABLE HANDLE WAFER FOR SILICON-ON INSULATOR DEVICES, and 62/316,524 filed Mar. 31, 2016, entitled VARIABLE PARAMETERS FOR SOI SUBSTRATE, the disclosure of each of which is hereby expressly incorporated by reference herein in its respective entirety.

### BACKGROUND

### Field

The present disclosure relates to silicon-on-insulator (SOI) substrate having one or more variable parameters.

### Description of the Related Art

In electronics applications, field-effect transistors (FETs) can be utilized as switches. Such switches can allow, for example, routing of radio-frequency (RF) signals in wireless devices. Such FETs can be implemented on silicon-on-insulator (SOI) substrates.

### SUMMARY

According to some implementations, the present disclosure relates to a radio-frequency device that includes a silicon-on-insulator substrate having an insulator layer and a handle wafer. The device further includes a plurality of field-effect transistors implemented over the insulator layer. Each transistor is separated from the handle wafer by a corresponding portion of the insulator layer. The corresponding portion of the insulator layer has an average thickness value such that the average thickness values associated with the plurality of transistors form a non-uniform distribution.

In some embodiments, the non-uniform distribution of the average thickness values can be selected to adjust a radio-frequency performance of some or all of the plurality of transistors. The insulator layer can include a buried oxide layer.

In some embodiments, the plurality of transistors can be implemented in a stack configuration and arranged in series along a length direction between an input node and an output node. The non-uniform distribution can be a function of the length direction.

In some embodiments, the non-uniform distribution can include a maximum average thickness associated with the first transistor adjacent the input node. In some embodiments, the non-uniform distribution can further include a generally decreasing average thickness values such that the last transistor from the input node has a minimum average thickness value. In some embodiments, the non-uniform distribution can further include a minimum average thickness value at a transistor that is between the first and last transistors from the input node.

In some embodiments, the plurality of transistors can be implemented in a switch having a plurality of stacks, with each stack having some of the plurality of transistors. The non-uniform distribution can include different average insulator thickness values among the plurality of stacks.

In some embodiments, the plurality of transistors can be implemented over the handle wafer having a non-uniform distribution of resistivity. The non-uniform distribution of resistivity of the handle wafer can be selected to adjust radio-frequency performance of some or all of the transistors.

In some implementations, the present disclosure relates to a method for fabricating a radio-frequency device. The method includes providing or forming a silicon-on-insulator substrate that includes an insulator layer and a handle wafer. The method further includes forming a plurality of field-effect transistors over the insulator layer, such that each transistor is separated from the handle wafer by a corresponding portion of the insulator layer. The corresponding portion of the insulator layer has an average thickness value such that the average thickness values associated with the plurality of transistors form a non-uniform distribution.

In some embodiments, the insulator layer can include a buried oxide layer. The forming of the plurality of transistors can include forming in a stack configuration such that the transistors are arranged in series along a length direction between an input node and an output node. The non-uniform distribution can be a function of the length direction.

In some embodiments, the non-uniform distribution can include a maximum average thickness associated with the first transistor adjacent the input node. In some embodiments, the non-uniform distribution can further include a generally decreasing average thickness values such that the last transistor from the input node has a minimum average thickness value. In some embodiments, the non-uniform distribution can further include a minimum average thickness value at a transistor that is between the first and last transistors from the input node.

In some embodiments, the plurality of transistors can be implemented in a switch having a plurality of stacks, with each stack having some of the plurality of transistors. The non-uniform distribution can include different average insulator thickness values among the plurality of stacks.

In some teachings, the present disclosure relates to a radio-frequency module that includes a packaging substrate configured to receive a plurality of devices, and a switching device mounted on the packaging substrate. The switching device includes a silicon-on-insulator substrate having an insulator layer and a handle wafer. The switching device further includes a plurality of field-effect transistors implemented over the insulator layer, with each transistor being separated from handle wafer by a corresponding portion of the insulator layer. The corresponding portion of the insulator layer has an average thickness value such that the average thickness values associated with the plurality of transistors form a non-uniform distribution.

In some implementations, the present disclosure relates to a wireless device that includes a transceiver configured to process radio-frequency signals, and a radio-frequency module in communication with the transceiver, and including a switching device having a silicon-on-insulator substrate that includes an insulator layer and a handle wafer. The switching device further includes a plurality of field-effect transistors implemented over the insulator layer, with each transistor being separated from the handle wafer by a corresponding portion of the insulator layer. The corresponding portion of the insulator layer has an average thickness value such that the average thickness values associated with the plurality of transistors form a non-uniform distribution. The wireless device further includes an antenna in communication with the radio-frequency module, and configured to facilitate transmission of a signal.

In accordance with some teachings, the present disclosure relates to a method for adjusting radio-frequency performance of a field-effect transistor implemented on a silicon-on-insulator substrate. The method includes determining a thickness of an insulator layer of the silicon-on-insulator substrate. The method further includes providing an electrical signal to a region underneath the transistor to adjust the radio-frequency performance of the transistor, with the electrical signal being selected based on the thickness of the insulator layer.

In some embodiments, the insulator layer can include a buried oxide layer. The electrical signal can include a DC voltage. The providing of the electrical signal can include delivering the DC voltage to a handle wafer of the silicon-on-insulator substrate through a substrate contact feature.

According to a number of teachings, the present disclosure relates to a radio-frequency device that includes a silicon-on-insulator substrate having an insulator layer and a handle wafer. The device further includes a plurality of field-effect transistors implemented over the insulator layer to cover a corresponding portion of the handle wafer having a non-uniform distribution of resistivity values.

In some embodiments, the non-uniform distribution of the resistivity values can be selected to adjust a radio-frequency performance of some or all of the plurality of transistors. The insulator layer can include a buried oxide layer.

In some embodiments, the plurality of transistors can be implemented in a stack configuration and arranged in series along a length direction between an input node and an output node. The non-uniform distribution can be a function of the length direction.

In some embodiments, the non-uniform distribution can include a maximum resistivity value associated with the first transistor adjacent the input node. In some embodiments, the non-uniform distribution can further include a generally decreasing resistivity values such that the last transistor from the input node has a minimum resistivity value. In some embodiments, the non-uniform distribution can further include a minimum resistivity value at a transistor that is between the first and last transistors from the input node.

In some embodiments, the plurality of transistors can be implemented in a switch having a plurality of stacks, with each stack having some of the plurality of transistors. The non-uniform distribution can include different resistivity values among the plurality of stacks.

In some embodiments, the plurality of transistors can be implemented over the insulator layer having a non-uniform distribution of average thickness values. The non-uniform distribution of the average thickness of the insulator layer can be selected to adjust radio-frequency performance of some or all of the transistors.

According to a number of implementations, the present disclosure relates to a method for fabricating a radio-frequency device. The method includes providing or forming a silicon-on-insulator substrate that includes an insulator layer and a handle wafer. The method further includes forming a plurality of field-effect transistors over the insulator layer, such that the transistors cover a corresponding portion of the handle wafer having a non-uniform distribution of resistivity values.

In some embodiments, the insulator layer can include a buried oxide layer. The forming of the plurality of transistors can include forming a stack configuration such that the transistors are arranged in series along a length direction between an input node and an output node. The non-uniform distribution can be a function of the length direction.

In some embodiments, the non-uniform distribution can include a maximum resistivity associated with the first transistor adjacent the input node. In some embodiments, the non-uniform distribution can further include a generally decreasing resistivity values such that the last transistor from the input node has a minimum resistivity value. In some embodiments, the non-uniform distribution can further include a minimum resistivity value at a transistor that is between the first and last transistors from the input node.

In some embodiments, the plurality of transistors can be implemented in a switch having a plurality of stacks, with each stack having some of the plurality of transistors. The non-uniform distribution can include different resistivity values among the plurality of stacks.

In some implementations, the present disclosure relates to a radio-frequency module that includes a packaging substrate configured to receive a plurality of devices, and a switching device mounted on the packaging substrate. The switching device includes a silicon-on-insulator substrate having an insulator layer and a handle wafer. The switching device further includes a plurality of field-effect transistors implemented over the insulator layer to cover a corresponding portion of the handle wafer having a non-uniform distribution of resistivity values.

In a number of implementations, the present disclosure relates to a wireless device that includes a transceiver configured to process radio-frequency signals, and a radio-frequency module in communication with the transceiver. The radio-frequency module includes a switching device having a silicon-on-insulator substrate that includes an insulator layer and a handle wafer. The switching device further includes a plurality of field-effect transistors implemented over the insulator layer to cover a corresponding portion of the handle wafer having a non-uniform distribution of resistivity values. The wireless device further includes an antenna in communication with the radio-frequency module, and configured to facilitate transmission of a signal.

In some implementations, the present disclosure relates to a method for adjusting radio-frequency performance of a field-effect transistor implemented on a silicon-on-insulator substrate. The method includes determining a resistivity of a handle wafer of the silicon-on-insulator substrate. The method further includes providing an electrical signal to a region underneath the transistor to adjust the radio-frequency performance of the transistor, with the electrical signal being selected based on the resistivity of the handle wafer.

In some embodiments, the insulator layer can include a buried oxide layer. The electrical signal can include a DC voltage. The providing of the electrical signal can include delivering the DC voltage to a handle wafer of the silicon-on-insulator substrate through a substrate contact feature.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIGS. 1A and 1B show side sectional and plan views of an example silicon-on-insulator (SOI) field-effect transistor (FET) device having an active FET implemented over a substrate such as a silicon substrate associated with a handle wafer.

FIGS. 2A-2C show various examples of SOI FET devices having one or more features as described herein.

FIG. 3 shows an example model of an SOI FET device having one or more features as described herein.

FIG. 4 shows an example of a stack having a plurality of SOI FET devices arranged in series between first and second nodes.

FIG. 5 shows an example switching configuration that can be implemented using a plurality of stacks.

FIG. 6 shows that in some embodiments, one or more features of the present disclosure can be implemented so that some or all of the example stacks of FIG. 5 are configured differently.

FIG. 7 shows an example stack similar to the example of FIG. 4.

FIGS. 8A-8D show non-limiting examples of how BOX layer thickness can vary as a function of position along a selected direction.

FIGS. 9A-9C show various examples of SOI FET devices having one or more features as described herein.

FIG. 10 shows that in some embodiments, one or more features of the present disclosure can be implemented so that some or all of the example stacks of FIG. 5 are configured differently.

FIG. 11 shows an example stack similar to the example of FIG. 4.

FIGS. 12A-12D show non-limiting examples of how handle wafer resistivity ρ_{HW} can vary as a function of position along the direction X.

FIG. 13 shows that in some embodiments, one or more features of the present disclosure can be implemented so that some or all of the example stacks of FIG. 5 are configured differently.

FIGS. 14A-14D show examples of different combinations of BOX layer thickness and handle wafer resistivity ρ_{HW} that can be implemented for a stack of SOI FET devices.

FIGS. 15A and 15B show plan and side views of a packaged module having one or more features as described herein.

FIG. 16 shows a schematic diagram of an example switching configuration that can be implemented in the module of FIGS. 15A and 15B.

FIG. 17 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

Disclosed herein are various examples related to field-effect transistors (FETs) and/or FET-based devices, such as those having silicon-on-insulator (SOI) process technology. Such FETs are utilized in many radio-frequency (RF) circuits, including those involving high performance, low loss, high linearity switches. In such RF switching circuits, performance advantage typically results from building a transistor in silicon, which sits on an insulator such as an insulating buried oxide (BOX). The BOX typically sits on a handle wafer, typically silicon, but can be glass, borosilicon glass, fused quartz, sapphire, silicon carbide, or any other electrically-insulating material.

In various examples herein, FETs are sometimes described in the context of such SOI technology. However, it will be understood that one or more features of the present disclosure can also be implemented in other types of FETs.

Among others, U.S. Provisional Application No. 62/316,521, filed Mar. 31, 2016, titled FIELD-EFFECT TRANSISTOR DEVICES HAVING PROXIMITY CONTACT FEATURES (the “'521” application), and which is expressly incorporated by reference in its entirely, and its disclosure is to be considered part of the specification of the present application, discloses various details on how FETs can be configured, including use of substrate biasing and/or proximity electrode. The '521 application also discloses examples of how FET devices having one or more features as described herein can be fabricated as wafers, as well as various applications that utilize such FET devices. The '521 application also discloses examples of various products that can include such FET devices. Accordingly, it will be understood that one or more features of the present disclosure can be implemented in such contexts disclosed in the '521 application, along with one or more of such features disclosed in the '521 application, in various applications disclosed in the '521 application, and/or in various products disclosed in the '521 application.

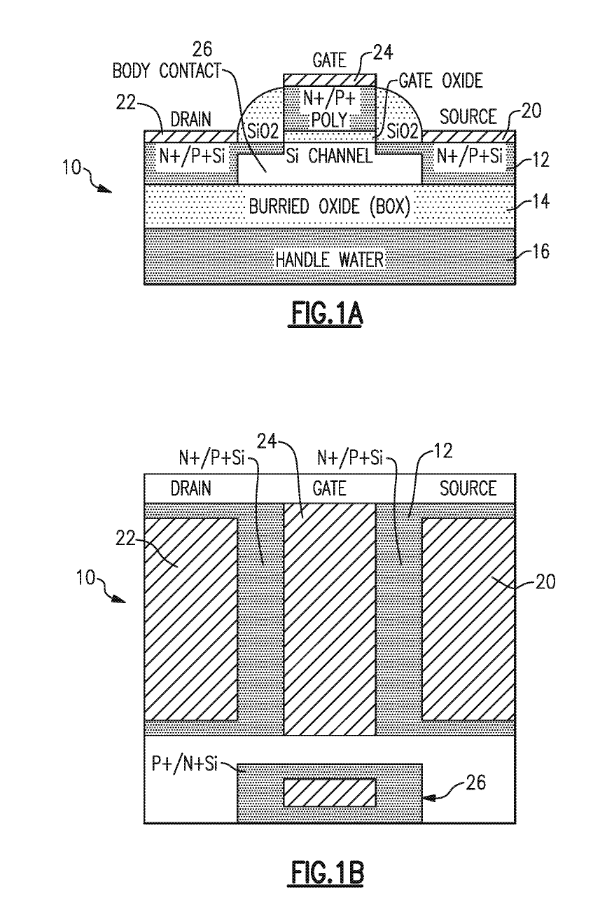

FIGS. 1A and 1B show side sectional and plan views of an example SOI FET device 10 having an active FET implemented over a substrate such as a silicon substrate associated with a handle wafer 16. Although described in the context of such a handle wafer, it will be understood that the substrate does not necessarily need to have functionality associated with a handle wafer.

An insulator layer such as a BOX layer 14 is shown to be formed over the handle wafer 16, and the active FET is shown to be formed based on an active silicon device 12 over the BOX layer 14. In various examples described herein, the active FET can be configured as an NPN or PNP device.

In the example of FIGS. 1A and 1B, terminals for the gate 24, source 20, drain 22 and body 26 are shown to be configured and provided so as to allow operation of the FET. It will be understood that in some embodiments, the source and the drain can be interchanged.

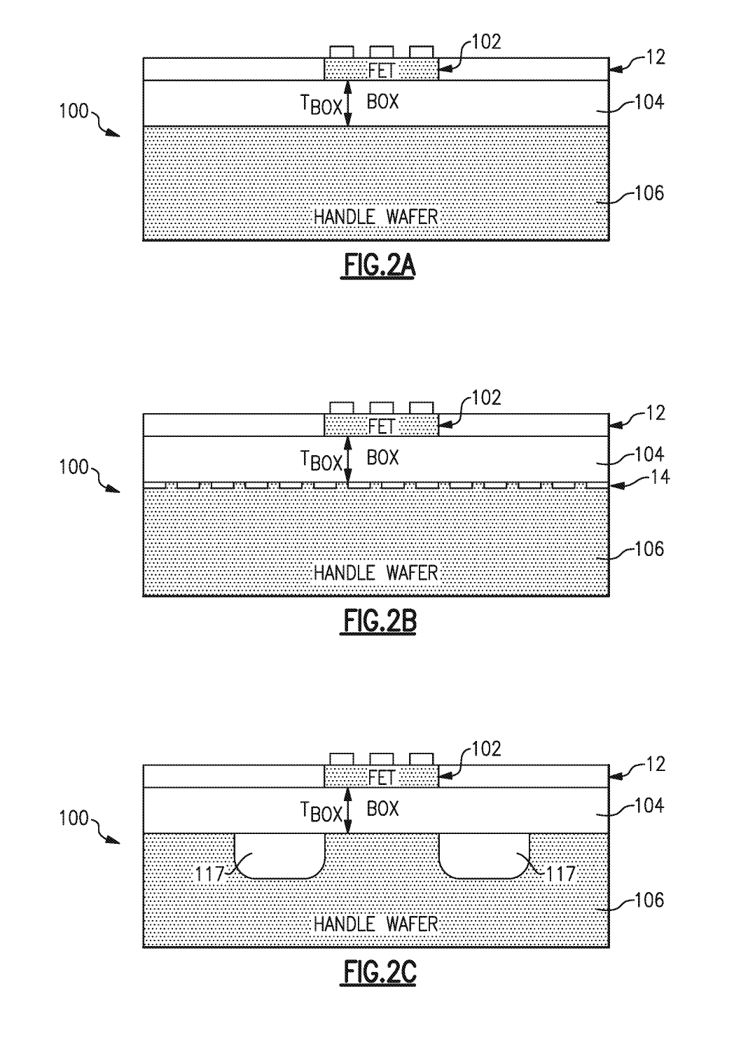

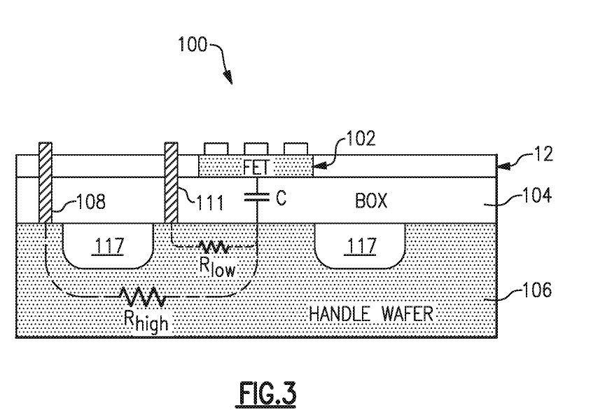

FIGS. 2A-2C show various examples of SOI FET devices 100 each having one or more features as described herein. In each of such example SOI FET devices, an insulator layer such as a BOX layer 104 is shown to be formed over a silicon (Si) handle wafer layer 106. An active Si layer 12 is shown to be formed over the BOX layer 104. Further, an active Si device (also referred to herein as an active FET, or a source/gate/drain (S/G/D) assembly) 102 is shown to be formed from the active Si layer. Contact features for the source, gate and drain are shown to be formed on the active FET. It will be understood that one or more metal layers and one or more layers of dielectric along with one or more passivation layers, one or more dielectric layers, or some combination thereof, can be formed to provide electrical connections for such contact features.

In the example of FIG. 2A, the BOX layer 104 can be generally directly above the handle wafer 106. In the example of FIG. 2B, an interface layer such as a trap-rich layer 14 can be implemented generally between the BOX layer 104 the handle wafer 106. In the example of FIG. 2C, the handle wafer 106 can include a plurality of doped regions 117 implemented to provide one or more functionalities similar to a trap-rich interface layer (e.g., 14 in FIG. 2B). It will be understood that one or more features of the present disclosure can also be implemented in other types of SOI substrate configurations.

In the examples of FIGS. 2A-2C, the BOX layer 104 is shown to have a thickness T_{BOX}. As described herein, such a BOX thickness can be adjusted to provide a desirable operating condition for the active FET 102. Accordingly, in some embodiments, T_{BOX} can vary at different implementation levels associated with the SOI FET device 100. Examples related to such variations are described herein in greater detail.

In some applications, an SOI FET device having one or more features as described herein can be modeled as shown in FIG. 3. The example of FIG. 3 is based on the example of FIG. 2C, but with a substrate contact feature 108 and a proximity electrode 111. Additional details concerning such substrate contact feature and a proximity electrode can be found in the '521 application.

Referring to FIG. 3, the BOX layer 104 being interposed between the active FET 102 and the handle wafer 106 can result in a capacitance C therebetween. Further, a resistance R can exist between the end of the proximity electrode 111 and the BOX/handle wafer interface. Accordingly, a series RC coupling can be provided between the proximity electrode 111 and the underside of the active FET 102. Thus, such a model coupling can be utilized to obtain a desirable operating environment for the active FET 102.

In the example of FIG. 3, a substrate contact feature 108 is also shown. Such a substrate contact feature is typically farther away from the active FET 102 than the proximity electrode 111. Accordingly, the resistance (R_{low}) between the proximity electrode 111 and the BOX/handle wafer interface is less than the resistance (R_{high}) between the substrate contact feature 108 and the BOX/handle wafer interface. Thus, the proximity electrode 111 can be utilized in situations where a low resistance coupling is desired, and the substrate contact feature can be utilized in situations where a high resistance coupling is desired.

In the example of FIG. 3, the BOX layer thickness T_{BOX} being adjustable can result in the capacitance C to be adjustable. Accordingly, the foregoing RC coupling can be adjusted in a desired manner to obtain a desirable operating environment for the active FET 102.

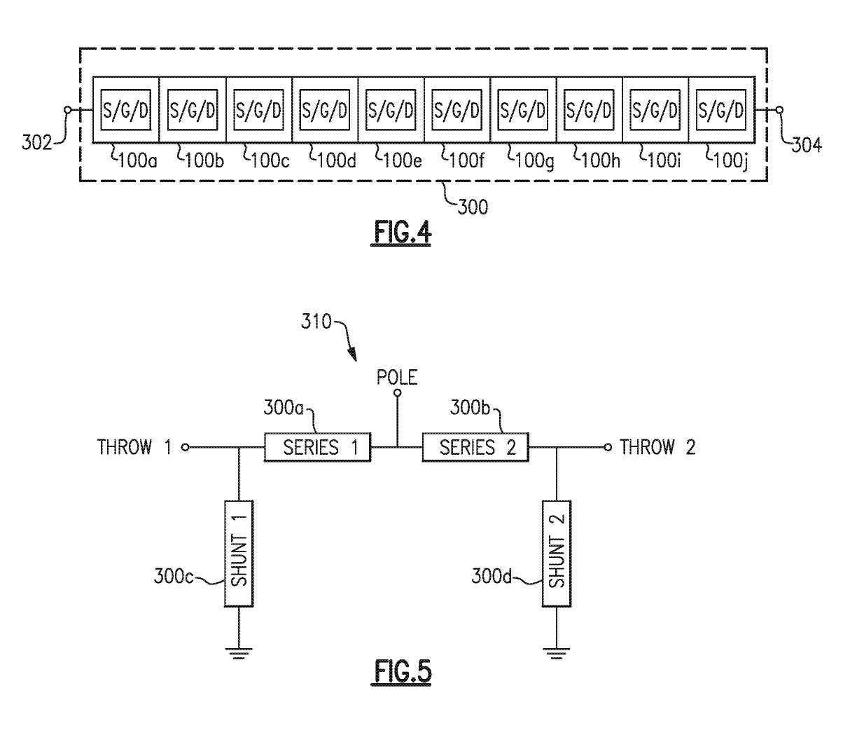

In some embodiments, a plurality of SOI FET devices can be implemented in a stack configuration. Examples related such a stack configuration can be found in the '521 application. FIG. 4 shows an example of a stack 300 having a plurality of SOI FET devices 100 arranged in series between first and second nodes 302, 304. Such nodes can be utilized as input and output nodes. It will be understood that other numbers of SOI FET devices can be utilized in a stack.

In the example of FIG. 4, the stack 300 is shown to include ten SOI FET devices 100a-100j. It will be understood that other numbers of SOI FET devices can also be utilized to form a stack.

FIG. 5 shows an example switching configuration 310 that can be formed using a plurality of stacks such as the example of FIG. 4. In the example of FIG. 5, the switching configuration 310 has a single-pole-double-throw (SPDT) configuration. It will be understood that other switching configurations can also be implemented. Examples of such switching configurations are disclosed in the '521 application.

In the SPDT example of FIG. 5, a first stack 300a can provide a switchable path (Series 1) between a pole (Pole) and a first throw (Throw 1), and a second stack 300b can provide a switchable path (Series 2) between the pole and a second throw (Throw 2). A switchable shunt path (Shunt 1) can be provided between the first throw and ground by a third stack 300c, and a switchable shunt path (Shunt 2) can be provided between the second throw and ground by a fourth stack 300d.

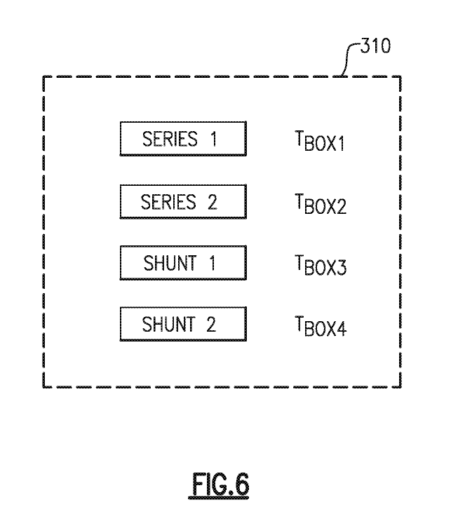

FIG. 6 shows that in some embodiments, one or more features of the present disclosure can be implemented so that some or all of the example stacks of FIG. 5 are configured differently.

For example, FIG. 6 shows that the four example stacks (Series 1, Series 2, Shunt 1, Shunt 2) can be configured to have respective BOX layer thickness values T_{BOX1}, T_{BOX2}, T_{BOX3}, T_{BOX4}. In some embodiments, some or all of such BOX layer thickness values T_{BOX1}, T_{BOX2}, T_{BOX3}, T_{BOX4} can be different. Examples of ranges of BOX layer thickness values are described herein in greater detail.

FIG. 7 shows an example stack 300 similar to the example of FIG. 4. In the example of FIG. 7, the stack 300 is depicted as extending along a direction indicated as X between its two nodes (302, 304 in FIG. 4).

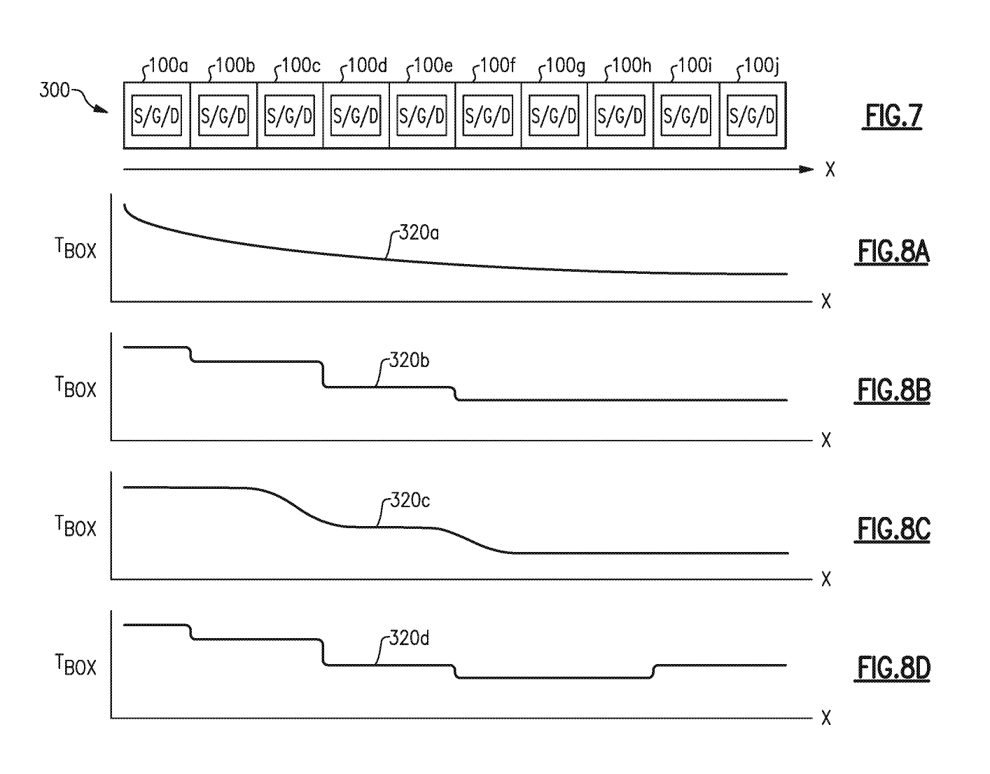

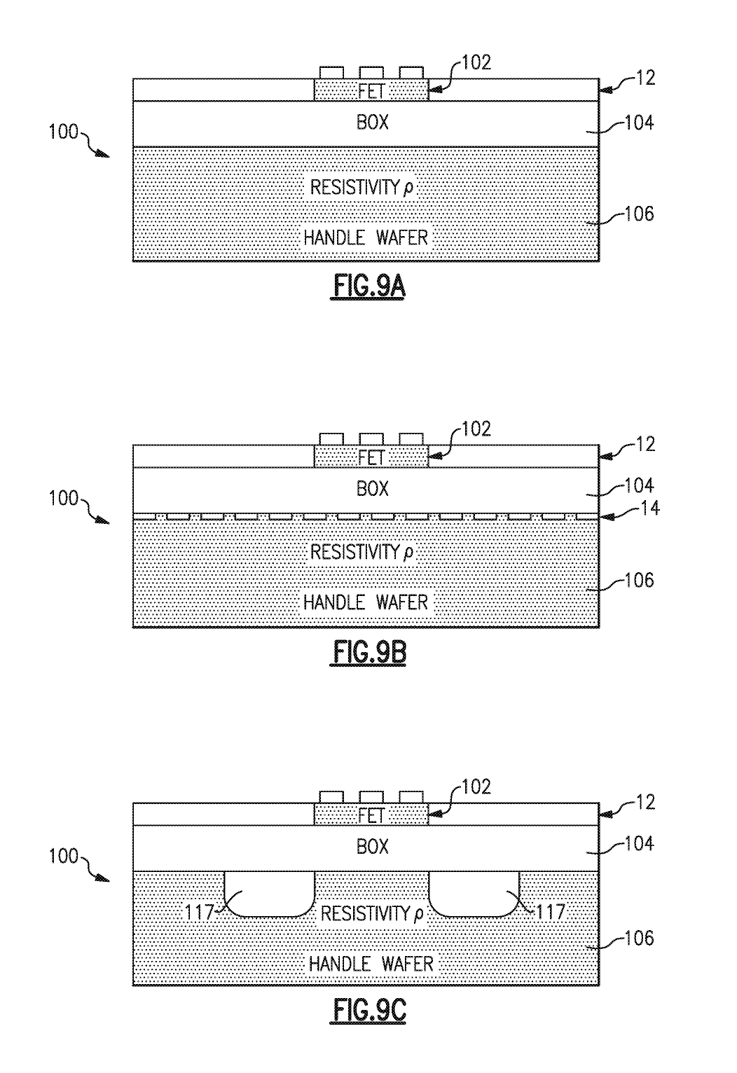

In some embodiments, the example stack 300 of FIG. 7 can be configured such that BOX layer thickness T_{BOX} varies within the stack. For example, FIGS. 8A-8D show non-limiting examples of how T_{BOX} can vary as a function of position along the direction X.

FIG. 8A shows that in some embodiments, variation in T_{BOX} can include a gradual increase and/or decrease so as to provide a relatively smooth curve 320a. In such an example configuration, the first SOI FET device 100a can have an average BOX layer thickness that is greater than an average BOX layer thickness of the second SOI FET device 100b, etc. Accordingly, and in the example context of the model RC coupling in FIG. 3, the RC value can vary relatively smoothly along the X-length of the stack 300.

FIG. 8B shows that in some embodiments, variation in T_{BOX} can include an approximately step increase and/or decrease so as to provide an approximately step-varying curve 320b. In such an example configuration, the first SOI FET device 100a is shown to have an approximately uniform BOX layer thickness that is greater than an approximately uniform BOX layer thickness of the second and third SOI FET devices 100b, 100c. Similarly, an approximately uniform BOX layer thickness of the fourth and fifth SOI FET devices 100d, 100e is less than that of the second and third SOI FET devices 100b, 100c. Similarly, an approximately uniform BOX layer thickness of the sixth to tenth SOI FET devices 100f-100j is less than that of the fourth and fifth SOI FET devices 100d, 100e. Accordingly, and in the example context of the model RC coupling in FIG. 3, the RC value can vary in approximate steps in groups of one or more SOI FET devices along the X-length of the stack 300.

FIG. 8C shows that in some embodiments, variation in T_{BOX} can include a group increase and/or decrease so as to provide a varying curve 320c. In such an example configuration, a processing technique may not provide sufficient resolution to allow formation of FET device dimension level variations similar to the example of FIG. 8B. In such a situation, the resulting variation can have a step-like variation, but transitions between the steps may be spread out significantly. Accordingly, and in the example context of the model RC coupling in FIG. 3, the RC value can vary in a similar manner along the X-length of the stack 300.

In the examples of FIGS. 8A-8C, variations in T_{BOX} are such that in each distribution, value of T_{BOX} generally decreases from the first SOI FET device 100a to the last SOI FET device 100j. Accordingly, the last SOI FET device 100j is shown to have the smallest T_{BOX} value, either by itself or with one or more adjacent SOI FET devices.

FIG. 8D shows that in some embodiments, a distribution of T_{BOX} values in a stack can be such that a minimum value is not at the end SOI FET device (e.g., the last SOI FET device 100j). For example, in FIG. 8D, variation in T_{BOX} can be similar to the example of FIG. 8B for the first eight SOI FET devices (100a-100h in FIG. 7), where T_{BOX} values decrease in a step-varying curve 320d. However, the last two SOI FET devices (100i, 100j in FIG. 7) are shown to have a T_{BOX} value that is larger than the previous value (e.g., T_{BOX} value associated with SOI FET devices 100f-100h). Accordingly, in the example of FIG. 8D, the minimum T_{BOX} value is associated with non-end SOI FET devices (e.g., 100f-100h), and not with the end SOI FET device 100j. Thus, and in the example context of the model RC coupling in FIG. 3, the RC value can vary accordingly along the X-length of the stack 300.

In some embodiments, a BOX layer having one or more features as described herein can have a thickness in a range of approximately 0.010 μm to 2 μm. In some embodiments, variation in T_{BOX} as described herein can be approximately continuous, or in steps in a range of, for example, 0.010 μm to 0.020 μm, 0.020 μm to 0.050 μm, 0.050 μm to 0.100 μm, 0.100 μm to 0.150 μm, 0.150 μm to 0.200 μm, 0.200 μm to 0.500 μm, 0.500 μm to 1.0 μm, or 1.0 μm to 2.0 μm.

It is noted that the foregoing variation in the BOX layer thickness is an example technique for providing a desirable operating condition for the corresponding SOI FET device(s). Such a desirable operating condition can include, for example, an appropriate configuration in the RC coupling model described in reference to FIG. 3.

It is further noted that since a wafer desiring to have a uniform BOX layer thickness can result in some variation in the actual BOX layer thickness (e.g., due to process variations), such variations can be compensated by, for example, the substrate biasing technique, the proximity electrode technique, or some combination thereof, so as to form a more uniform operating condition for one or more SOI FET devices of interest. As described herein, such SOI FET device(s) can be part of a stack, and such a stack can be part of a switch circuit. Accordingly, it will be understood that techniques such as substrate biasing and/or proximity electrode can be applied differently at the SOI FET device level (e.g., to have a non-uniform application in a given stack), and/or at the stack level (e.g., to provide non-uniform application among the stacks of a given switch circuit).

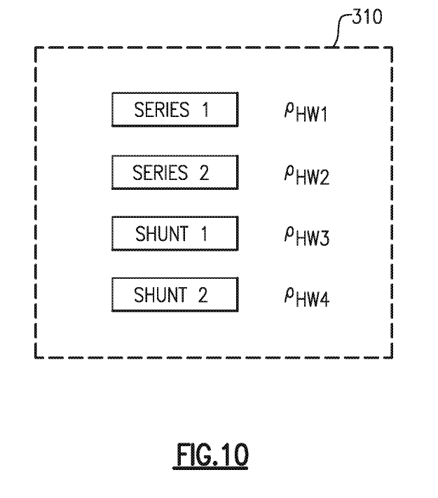

FIGS. 9A-9C show various examples of SOI FET devices 100 each having one or more features as described herein. In each of such example SOI FET devices, an insulator layer such as a BOX layer 104 is shown to be formed over a silicon (Si) handle wafer layer 106. An active Si layer 12 is shown to be formed over the BOX layer 104. Further, an active Si device (also referred to herein as an active FET, or a source/gate/drain (S/G/D) assembly) 102 is shown to be formed from the active Si layer. Contact features for the source, gate and drain are shown to be formed on the active FET. It will be understood that one or more metal layers and one or more layers of dielectric along with one or more passivation layers, one or more dielectric layers, or some combination thereof, can be formed to provide electrical connections for such contact features.

In the example of FIG. 9A, the BOX layer 104 can be generally directly above the handle wafer 106. In the example of FIG. 9B, an interface layer such as a trap-rich layer 14 can be implemented generally between the BOX layer 104 the handle wafer 106. In the example of FIG. 9C, the handle wafer 106 can include a plurality of doped regions 117 implemented to provide one or more functionalities similar to a trap-rich interface layer (e.g., 14 in FIG. 9B). It will be understood that one or more features of the present disclosure can also be implemented in other types of SOI substrate configurations.

In the examples of FIGS. 9A-9C, the handle wafer 106 is shown to have a resistivity ρ. As described herein, such a handle wafer resistivity can be adjusted to provide a desirable operating condition for the active FET 102. Accordingly, in some embodiments, ρ can vary at different implementation levels associated with the SOI FET device 100. Examples related to such variations are described herein in greater detail.

In some applications, an SOI FET device having one or more features as described herein can be modeled as described herein in reference to FIG. 3. Referring to FIG. 3, the BOX layer 104 being interposed between the active FET 102 and the handle wafer 106 can result in a capacitance C therebetween. Further, a resistance R can exist between the end of the proximity electrode 111 and the BOX/handle wafer interface. Accordingly, a series RC coupling can be provided between the proximity electrode 111 and the underside of the active FET 102. Thus, such a model coupling can be utilized to obtain a desirable operating environment for the active FET 102.

In the example of FIG. 3, a substrate contact feature 108 is also shown. Such a substrate contact feature is typically farther away from the active FET 102 than the proximity electrode 111. Accordingly, the resistance (R_{low}) between the proximity electrode 111 and the BOX/handle wafer interface is less than the resistance (R_{high}) between the substrate contact feature 108 and the BOX/handle wafer interface. Thus, the proximity electrode 111 can be utilized in situations where a low resistance coupling is desired, and the substrate contact feature can be utilized in situations where a high resistance coupling is desired.

In the example of FIG. 3, the handle wafer resistivity p being adjustable can result in the handle wafer resistance (e.g., R_{low} and/or R_{high}) to be adjustable. Accordingly, the foregoing RC coupling can be adjusted in a desired manner to obtain a desirable operating environment for the active FET 102.

In some embodiments, a plurality of SOI FET devices can be implemented in a stack configuration. Examples related such a stack configuration can be found in the '521 application. As described herein in reference to FIG. 4, an example stack 300 can include a plurality of SOI FET devices 100 arranged in series between first and second nodes 302, 304. Such nodes can be utilized as input and output nodes. It will be understood that other numbers of SOI FET devices can be utilized in a stack.

In the example of FIG. 4, the stack 300 is shown to include ten SOI FET devices 100a-100j. It will be understood that other numbers of SOI FET devices can also be utilized to form a stack.

As also described herein in reference to FIG. 5, an example switching configuration 310 can be formed using a plurality of stacks such as the example of FIG. 4. In the example of FIG. 5, the switching configuration 310 has a single-pole-double-throw (SPDT) configuration. It will be understood that other switching configurations can also be implemented. Examples of such switching configurations are disclosed in the '521 application.

In the SPDT example of FIG. 5, a first stack 300a can provide a switchable path (Series 1) between a pole (Pole) and a first throw (Throw 1), and a second stack 300b can provide a switchable path (Series 2) between the pole and a second throw (Throw 2). A switchable shunt path (Shunt 1) can be provided between the first throw and ground by a third stack 300c, and a switchable shunt path (Shunt 2) can be provided between the second throw and ground by a fourth stack 300d.

FIG. 10 shows that in some embodiments, one or more features of the present disclosure can be implemented so that some or all of the example stacks of FIG. 5 are configured differently.

For example, FIG. 10 shows that the four example stacks (Series 1, Series 2, Shunt 1, Shunt 2) can be configured to have respective handle wafer resistivity values ρ_{HW1}, ρ_{HW2}, ρ_{HW3}, ρ_{HW4}. In some embodiments, some or all of such handle wafer resistivity values ρ_{HW1}, ρ_{HW2}, ρ_{HW3}, ρ_{HW4} can be different. Examples of ranges of handle wafer resistivity values are described herein in greater detail.

FIG. 11 shows an example stack 300 similar to the example of FIG. 4. In the example of FIG. 11, the stack 300 is depicted as extending along a direction indicated as X between its two nodes (302, 304 in FIG. 4).

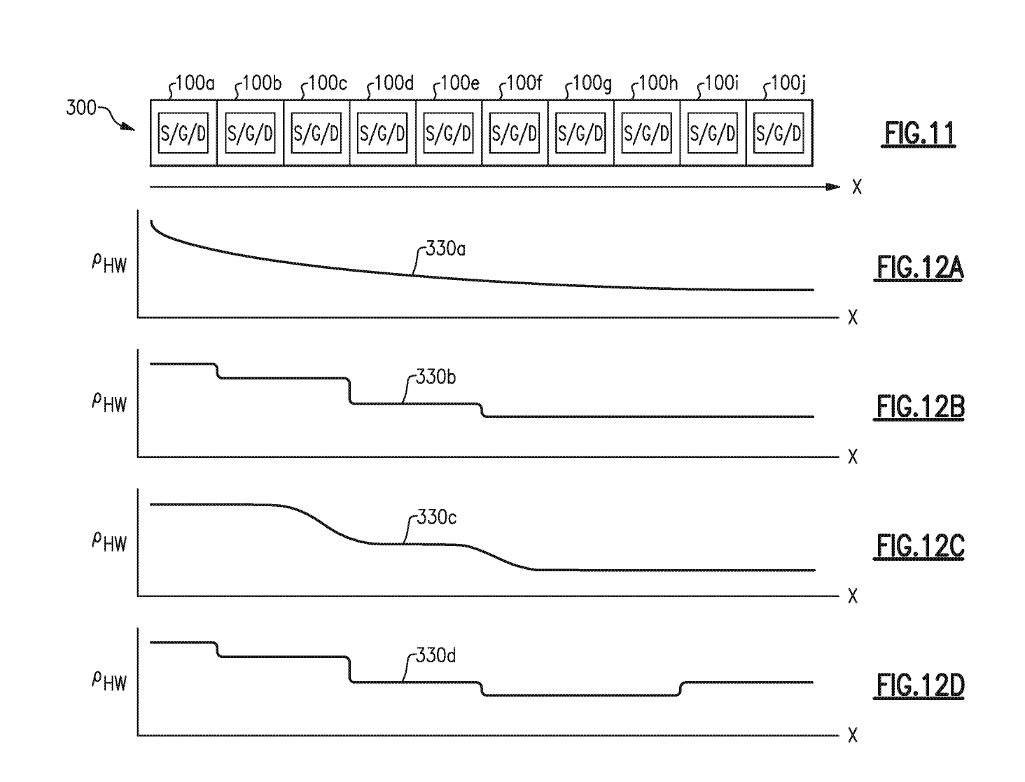

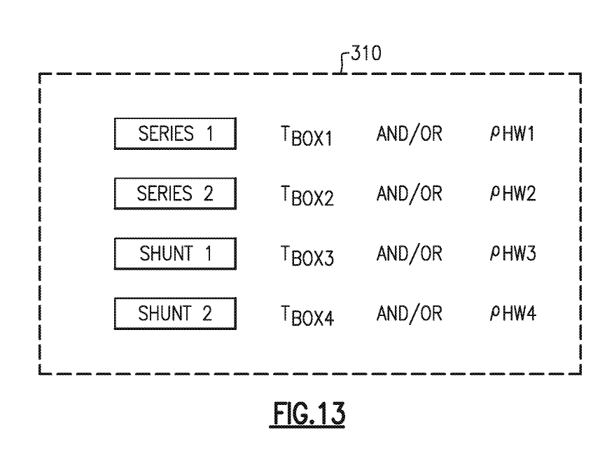

In some embodiments, the example stack 300 of FIG. 11 can be configured such that handle wafer resistivity ρ_{HW} varies within the stack. For example, FIGS. 12A-12D show non-limiting examples of how ρ_{HW} can vary as a function of position along the direction X.

FIG. 12A shows that in some embodiments, variation in ρ_{HW} can include a gradual increase and/or decrease so as to provide a relatively smooth curve 320a. In such an example configuration, the first SOI FET device 100a can have an average handle wafer resistivity that is greater than an average handle wafer resistivity of the second SOI FET device 100b, etc. Accordingly, and in the example context of the model RC coupling in FIG. 3, the RC value can vary relatively smoothly along the X-length of the stack 300.

FIG. 12B shows that in some embodiments, variation in ρ_{HW} can include an approximately step increase and/or decrease so as to provide an approximately step-varying curve 320b. In such an example configuration, the first SOI FET device 100a is shown to have an approximately uniform handle wafer resistivity that is greater than an approximately uniform handle wafer resistivity of the second and third SOI FET devices 100b, 100c. Similarly, an approximately uniform handle wafer resistivity of the fourth and fifth SOI FET devices 100d, 100e is less than that of the second and third SOI FET devices 100b, 100c. Similarly, an approximately uniform handle wafer resistivity of the sixth to tenth SOI FET devices 100f-100j is less than that of the fourth and fifth SOI FET devices 100d, 100e. Accordingly, and in the example context of the model RC coupling in FIG. 3, the RC value can vary in approximate steps in groups of one or more SOI FET devices along the X-length of the stack 300.

FIG. 12C shows that in some embodiments, variation in ρ_{HW} can include a group increase and/or decrease so as to provide a varying curve 320c. In such an example configuration, a processing technique may not provide sufficient resolution to allow formation of FET device dimension level variations similar to the example of FIG. 12B. In such a situation, the resulting variation can have a step-like variation, but transitions between the steps may be spread out significantly. Accordingly, and in the example context of the model RC coupling in FIG. 3, the RC value can vary in a similar manner along the X-length of the stack 300.

In the examples of FIGS. 12A-12C, variations in ρ_{HW} are such that in each distribution, value of ρ_{HW} generally decreases from the first SOI FET device 100a to the last SOI FET device 100j. Accordingly, the last SOI FET device 100j is shown to have the smallest ρ_{HW} value, either by itself or with one or more adjacent SOI FET devices.

FIG. 12D shows that in some embodiments, a distribution of ρ_{HW} values in a stack can be such that a minimum value is not at the end SOI FET device (e.g., the last SOI FET device 100j). For example, in FIG. 12D, variation in ρ_{HW} can be similar to the example of FIG. 12B for the first eight SOI FET devices (100a-100h in FIG. 11), where ρ_{HW} values decrease in a step-varying curve 330d. However, the last two SOI FET devices (100i, 100j in FIG. 11) are shown to have a ρ_{HW} value that is larger than the previous value (e.g., ρ_{HW} value associated with SOI FET devices 100f-100h). Accordingly, in the example of FIG. 12D, the minimum ρ_{HW} value is associated with non-end SOI FET devices (e.g., 100f-100h), and not with the end SOI FET device 100j. Thus, and in the example context of the model RC coupling in FIG. 3, the RC value can vary accordingly along the X-length of the stack 300.

In some embodiments, a handle wafer having one or more features as described herein can have a resistivity in a range of approximately 0.100K Ωm to 20K Ωm. In some embodiments, variation in ρ_{HW} as described herein can be approximately continuous, or in steps in a range of, for example, 0.100K Ωm to 0.200K Ωm, 0.200K Ωm to 0.500K Ωm, 0.500K Ωm to 1.00K Ωm, 1.00K Ωm to 2.00K Ωm, 2.00K Ωm to 3.00K Ωm, 3.00K Ωm to 4.00K Ωm, 4.00K Ωm to 5.00K Ωm, or 5.00K Ωm to 10.00K Ωm.

It is noted that the foregoing variation in the handle wafer resistivity is an example technique for providing a desirable operating condition for the corresponding SOI FET device(s). Such a desirable operating condition can include, for example, an appropriate configuration in the RC coupling model described in reference to FIG. 3.

It is further noted that since a handle wafer desiring to have a uniform resistivity can result in some variation in the actual resistivity (e.g., due to process variations), such variations can be compensated by, for example, the substrate biasing technique, the proximity electrode technique, or some combination thereof, so as to form a more uniform operating condition for one or more SOI FET devices of interest. As described herein, such SOI FET device(s) can be part of a stack, and such a stack can be part of a switch circuit. Accordingly, it will be understood that techniques such as substrate biasing and/or proximity electrode can be applied differently at the SOI FET device level (e.g., to have a non-uniform application in a given stack), and/or at the stack level (e.g., to provide non-uniform application among the stacks of a given switch circuit).

In some embodiments, an SOI FET device can include either or both of the BOX thickness variation feature (e.g., as shown in FIGS. 2A-2C) and the handle wafer resistivity variation feature (e.g., as shown in FIGS. 9A-9C).

As described herein in reference to FIG. 3, an SOI FET device having one or more features as described herein can be modeled. Referring to FIG. 3, the BOX layer 104 being interposed between the active FET 102 and the handle wafer 106 can result in a capacitance C therebetween. Further, a resistance R can exist between the end of the proximity electrode 111 and the BOX/handle wafer interface. Accordingly, a series RC coupling can be provided between the proximity electrode 111 and the underside of the active FET 102. Thus, such a model coupling can be utilized to obtain a desirable operating environment for the active FET 102.

In the example of FIG. 3, a substrate contact feature 108 is also shown. Such a substrate contact feature is typically farther away from the active FET 102 than the proximity electrode 111. Accordingly, the resistance (R_{low}) between the proximity electrode 111 and the BOX/handle wafer interface is less than the resistance (R_{high}) between the substrate contact feature 108 and the BOX/handle wafer interface. Thus, the proximity electrode 111 can be utilized in situations where low resistance coupling is desired, and the substrate contact feature can be utilized in situations where such high resistance coupling is desired.

In the example of FIG. 3, the BOX layer thickness T_{BOX} being adjustable can result in the capacitance C to be adjustable. Also, the handle wafer resistivity p being adjustable can result in the handle wafer resistance (e.g., R_{low} and/or R_{high}) to be adjustable. Accordingly, either or both of the BOX capacitance and the handle wafer resistance can be adjusted in a desired manner to obtain a desirable operating environment for the active FET 102.

In some embodiments, and as described herein, a plurality of SOI FET devices can be implemented in a stack configuration. Examples related such a stack configuration can be found in the '521 application. As described herein in reference to FIG. 4, an example stack 300 having a plurality of SOI FET devices 100 can be arranged in series between first and second nodes 302, 304. Such nodes can be utilized as input and output nodes. It will be understood that other numbers of SOI FET devices can be utilized in a stack.

In the example of FIG. 4, the stack 300 is shown to include ten SOI FET devices 100a-100j. It will be understood that other numbers of SOI FET devices can also be utilized to form a stack.

As described herein in reference to FIG. 5, an example switching configuration 310 can be formed using a plurality of stacks such as the example of FIG. 4. In the example of FIG. 5, the switching configuration 310 has a single-pole-double-throw (SPDT) configuration. It will be understood that other switching configurations can also be implemented. Examples of such switching configurations are disclosed in the '521 application.

In the SPDT example of FIG. 5, a first stack 300a can provide a switchable path (Series 1) between a pole (Pole) and a first throw (Throw 1), and a second stack 300b can provide a switchable path (Series 2) between the pole and a second throw (Throw 2). A switchable shunt path (Shunt 1) can be provided between the first throw and ground by a third stack 300c, and a switchable shunt path (Shunt 2) can be provided between the second throw and ground by a fourth stack 300d.

FIG. 13 shows that in some embodiments, one or more features of the present disclosure can be implemented so that some or all of the example stacks of FIG. 5 are configured differently.

For example, FIG. 13 shows that the four example stacks (Series 1, Series 2, Shunt 1, Shunt 2) can be configured to have respective BOX layer thickness values T_{BOX1}, T_{BOX2}, T_{BOX3}, T_{BOX4}. In some embodiments, some or all of such BOX layer thickness values T_{BOX1}, T_{BOX2}, T_{BOX3}, T_{BOX4} can be different. Examples of ranges of BOX layer thickness values are described herein in greater detail.

FIG. 13 also shows that the four example stacks (Series 1, Series 2, Shunt 1, Shunt 2) can be configured to have respective handle wafer resistivity values ρ_{HW1}, ρ_{HW2}, ρ_{HW3}, ρ_{HW4}. In some embodiments, some or all of such handle wafer resistivity values ρ_{HW1}, ρ_{HW2}, ρ_{HW3}, ρ_{HW4} can be different. Examples of ranges of handle wafer resistivity values are described herein in greater detail.

Accordingly, either or both of the BOX capacitance and the handle wafer resistance can be adjusted for different stacks in a switching configuration to obtain a desirable operating environment for the active FET 102.

As described herein in reference to FIGS. 7 and 11, example stacks 300 similar to the example of FIG. 4 can be implemented. In the examples of FIGS. 7 and 11, each stack 300 is depicted as extending along a direction indicated as X between its two nodes (302, 304 in FIG. 4).

In some embodiments, and as described herein, the example stack 300 of FIG. 7 can be configured such that BOX layer thickness T_{BOX} varies within the stack. For example, FIGS. 8A-8D show non-limiting examples of how T_{BOX} can vary as a function of position along the direction X.

In some embodiments, and as described herein, the example stack 300 of FIG. 11 can be configured such that handle wafer resistivity ρ_{HW} varies within the stack. For example, FIGS. 12A-12D show non-limiting examples of how ρ_{HW} can vary as a function of position along the direction X.

In some embodiments, and as described herein, a stack having one or more features of the present disclosure can include either or both of the foregoing variation characteristics (e.g., variation in T_{BOX} and variation in ρ_{HW}) within the stack.

In some embodiments, a BOX layer having one or more features as described herein can have a thickness in a range of approximately 0.010 μm to 2 μm. In some embodiments, variation in T_{BOX} as described herein can be approximately continuous, or in steps in a range of, for example, 0.010 μm to 0.020 μm, 0.020 μm to 0.050 μm, 0.050 μm to 0.100 μm, 0.100 μm to 0.150 μm, 0.150 μm to 0.200 μm, 0.200 μm to 0.500 μm, 0.500 μm to 1.0 μm, or 1.0 μm to 2.0 μm.

It is noted that the foregoing variation in the BOX layer thickness is an example technique for providing a desirable operating condition for the corresponding SOI FET device(s). Such a desirable operating condition can include, for example, an appropriate configuration in the RC coupling model described in reference to FIG. 3.

It is further noted that since a wafer desiring to have a uniform BOX layer thickness can result in some variation in the actual BOX layer thickness (e.g., due to process variations), such variations can be compensated by, for example, the substrate biasing technique, the proximity electrode technique, or some combination thereof, so as to form a more uniform operating condition for one or more SOI FET devices of interest. As described herein, such SOI FET device(s) can be part of a stack, and such a stack can be part of a switch circuit. Accordingly, it will be understood that techniques such as substrate biasing and/or proximity electrode can be applied differently at the SOI FET device level (e.g., to have a non-uniform application in a given stack), and/or at the stack level (e.g., to provide non-uniform application among the stacks of a given switch circuit).

In some embodiments, a handle wafer having one or more features as described herein can have a resistivity in a range of approximately 0.100K Ωm to 20K Ωm. In some embodiments, variation in ρ_{HW} as described herein can be approximately continuous, or in steps in a range of, for example, 0.100K Ωm to 0.200K Ωm, 0.200K Ωm to 0.500K Ωm, 0.500K Ωm to 1.00K Ωm, 1.00K Ωm to 2.00K Ωm, 2.00K Ωm to 3.00K Ωm, 3.00K Ωm to 4.00K Ωm, 4.00K Ωm to 5.00K Ωm, or 5.00K Ωm to 10.00K Ωm.

It is noted that the foregoing variation in the handle wafer resistivity is an example technique for providing a desirable operating condition for the corresponding SOI FET device(s). Such a desirable operating condition can include, for example, an appropriate configuration in the RC coupling model described in reference to FIG. 3.

It is further noted that since a handle wafer desiring to have a uniform resistivity can result in some variation in the actual resistivity (e.g., due to process variations), such variations can be compensated by, for example, the substrate biasing technique, the proximity electrode technique, or some combination thereof, so as to form a more uniform operating condition for one or more SOI FET devices of interest. As described herein, such SOI FET device(s) can be part of a stack, and such a stack can be part of a switch circuit. Accordingly, it will be understood that techniques such as substrate biasing and/or proximity electrode can be applied differently at the SOI FET device level (e.g., to have a non-uniform application in a given stack), and/or at the stack level (e.g., to provide non-uniform application among the stacks of a given switch circuit).

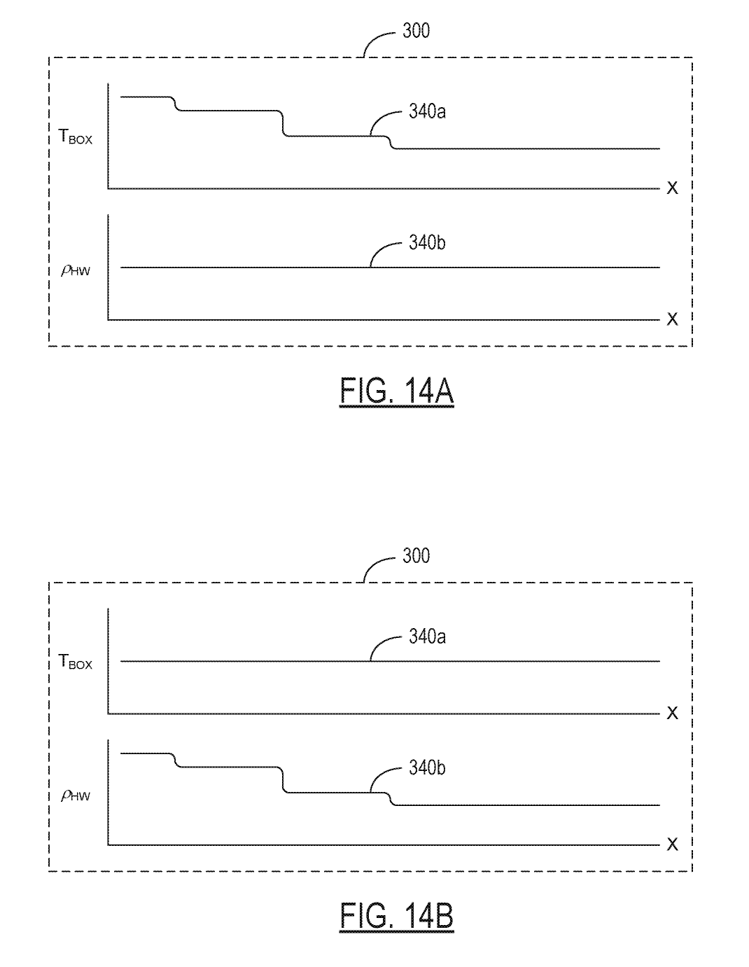

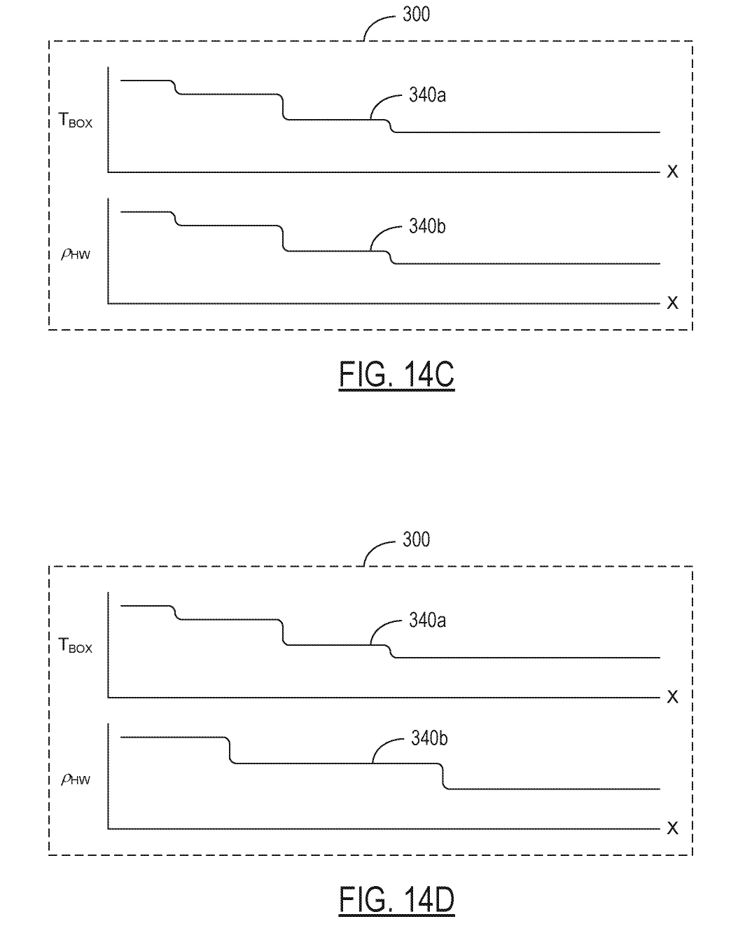

FIGS. 14A-14D show examples of different combinations of BOX layer thickness (T_{BOX}) and handle wafer resistivity (ρ_{HW}) that can be implemented for a stack 300 of SOI FET devices. FIG. 14A shows that in some embodiments, a stack 300 of SOI FET devices can be configured to include a varying distribution of T_{BOX} values (curve 340a) across the stack 300 (e.g., including the examples described herein in reference to FIGS. 6-8), and an approximately uniform distribution of ρ_{HW} (curve 340b) across the stack 300. In such a configuration, and in the example context of the model RC coupling in FIG. 3, the RC value can vary based on the variation of T_{BOX} values.

FIG. 14B shows that in some embodiments, a stack 300 of SOI FET devices can be configured to include an approximately uniform distribution of T_{BOX} (curve 340a) across the stack 300, and a varying distribution of ρ_{HW} (curve 340b) across the stack 300 (e.g., including the examples described herein in reference to FIGS. 10-12). In such a configuration, and in the example context of the model RC coupling in FIG. 3, the RC value can vary based on the variation of ρ_{HW} values.

FIGS. 14C and 14D show that in some embodiments, a stack 300 of SOI FET devices can be configured to include a varying distribution of T_{BOX} values (curve 340a) across the stack 300 (e.g., including the examples described herein in reference to FIGS. 6-8), and a varying distribution of ρ_{HW} (curve 340b) across the stack 300 (e.g., including the examples described herein in reference to FIGS. 10-12). FIG. 14C shows that in some embodiments, the variation in T_{BOX} can generally track the variation in ρ_{HW}. FIG. 14D shows that in some embodiments, the variation in T_{BOX} can have a different profile than the variation in ρ_{HW}. In such configurations of FIGS. 14C and 14D, and in the example context of the model RC coupling in FIG. 3, the RC values can vary based on the variations of combinations of T_{BOX} values and ρ_{HW} values.

### Examples Related to Implementations in Products

Various examples of SOI FET devices, circuits based on such devices, and bias/coupling configurations for such devices and circuits as described herein can be implemented in a number of different ways and at different product levels. Some of such product implementations are described by way of examples.

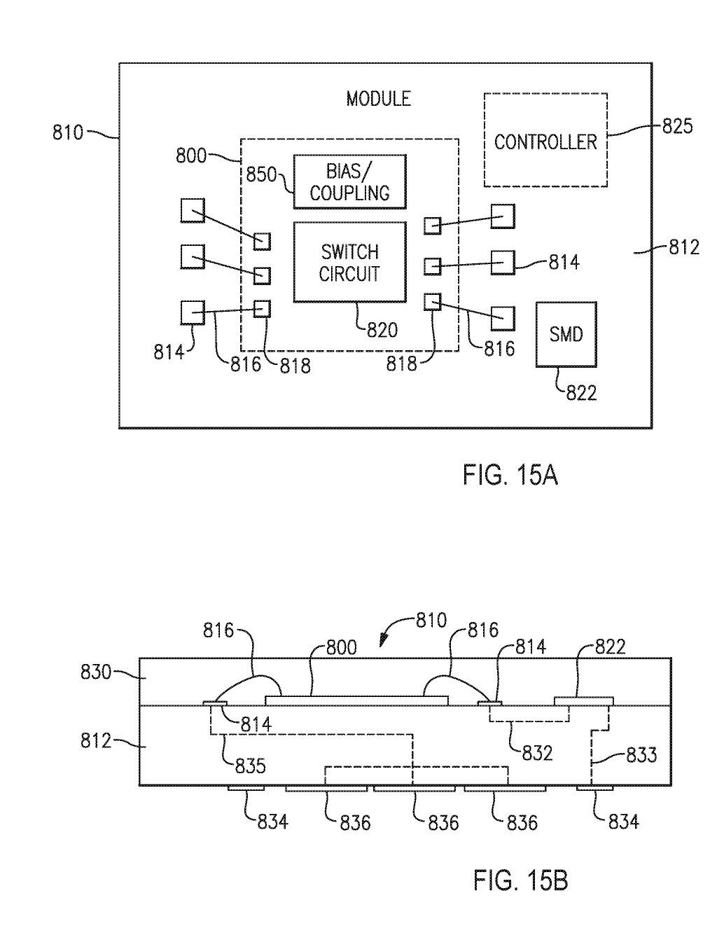

In some embodiments, one or more die having one or more features described herein can be implemented in a packaged module. An example of such a module is shown in FIGS. 15A (plan view) and 15B (side view). Although described in the context of both of the switch circuit and the bias/coupling circuit being on the same die, it will be understood that packaged modules can be based on other configurations.

A module 810 is shown to include a packaging substrate 812. Such a packaging substrate can be configured to receive a plurality of components, and can include, for example, a laminate substrate. The components mounted on the packaging substrate 812 can include one or more die. In the example shown, a die 800 having a switching circuit 820 and a bias/coupling circuit 850 is shown to be mounted on the packaging substrate 812. The die 800 can be electrically connected to other parts of the module (and with each other where more than one die is utilized) through connections such as connection-wirebonds 816. Such connection-wirebonds can be formed between contact pads 818 formed on the die 800 and contact pads 814 formed on the packaging substrate 812. In some embodiments, one or more surface mounted devices (SMDs) 822 can be mounted on the packaging substrate 812 to facilitate various functionalities of the module 810.

In some embodiments, the packaging substrate 812 can include electrical connection paths for interconnecting the various components with each other and/or with contact pads for external connections. For example, a connection path 832 is depicted as interconnecting the example SMD 822 and the die 800. In another example, a connection path 833 is depicted as interconnecting the SMD 822 with an external-connection contact pad 834. In yet another example a connection path 835 is depicted as interconnecting the die 800 with ground-connection contact pads 836.

In some embodiments, a space above the packaging substrate 812 and the various components mounted thereon can be filled with an overmold structure 830. Such an overmold structure can provide a number of desirable functionalities, including protection for the components and wirebonds from external elements, and easier handling of the packaged module 810.

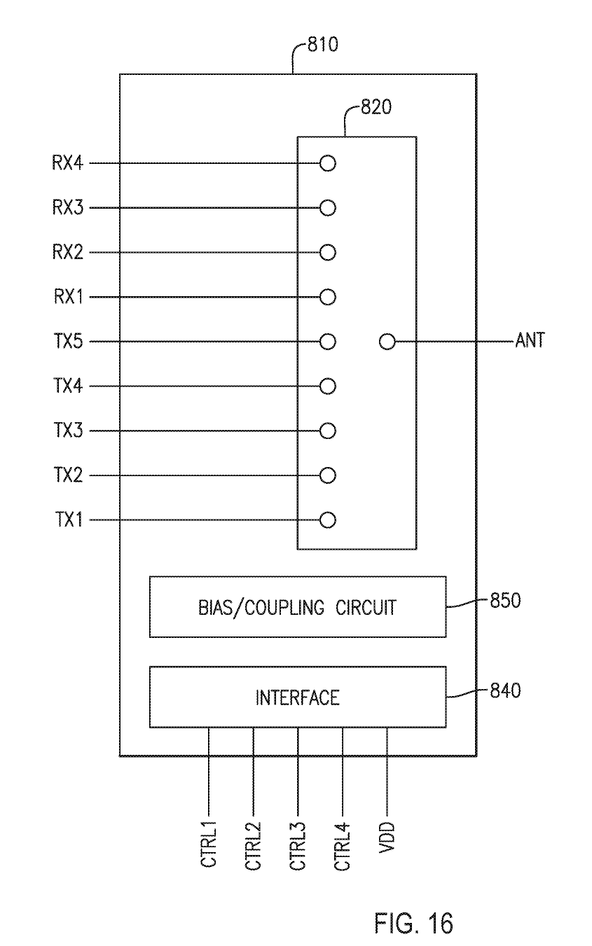

FIG. 16 shows a schematic diagram of an example switching configuration that can be implemented in the module 810 described in reference to FIGS. 15A and 15B. In the example, the switch circuit 820 is depicted as being an SP9T switch, with the pole being connectable to an antenna and the throws being connectable to various Rx and Tx paths. Such a configuration can facilitate, for example, multi-mode multi-band operations in wireless devices. As described herein, various switching configurations (e.g., including those configured for more than one antenna) can be implemented for the switch circuit 820. As also described herein, one or more throws of such switching configurations can be connectable to corresponding path(s) configured for TRx operations.

The module 810 can further include an interface for receiving power (e.g., supply voltage VDD) and control signals to facilitate operation of the switch circuit 820 and/or the bias/coupling circuit 850. In some implementations, supply voltage and control signals can be applied to the switch circuit 820 via the bias/coupling circuit 850.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

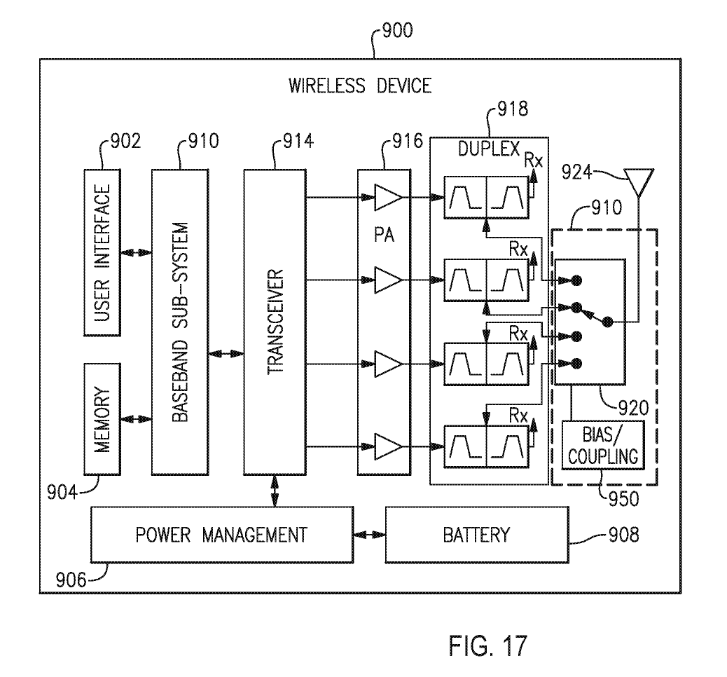

FIG. 17 depicts an example wireless device 900 having one or more advantageous features described herein. In the context of various switches and various biasing/coupling configurations as described herein, a switch 920 and a bias/coupling circuit 950 can be part of a module 910. In some embodiments, such a switch module can facilitate, for example, multi-band multi-mode operations of the wireless device 900.

In the example wireless device 900, a power amplifier (PA) assembly 916 having a plurality of PAs can provide one or more amplified RF signals to the switch 920 (via an assembly of one or more duplexers 918), and the switch 920 can route the amplified RF signal(s) to one or more antennas. The PAs 916 can receive corresponding unamplified RF signal(s) from a transceiver 914 that can be configured and operated in known manners. The transceiver 914 can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 910.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexers 918 can allow transmit and receive operations to be performed simultaneously using a common antenna (e.g., 924). In FIG. 17, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

### General Comments

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio-frequency device comprising:
a silicon-on-insulator substrate including an insulator layer and a handle wafer; and
a plurality of field-effect transistors implemented over the insulator layer, each transistor separated from the handle wafer by a corresponding portion of the insulator layer, the corresponding portion of the insulator layer having an average thickness value such that the average thickness values associated with the plurality of transistors form a non-uniform distribution.

2. The radio-frequency device of claim 1 wherein the non-uniform distribution of the average thickness values is selected to adjust a radio-frequency performance of some or all of the plurality of transistors.

3. The radio-frequency device of claim 2 wherein the insulator layer includes a buried oxide layer.

4. The radio-frequency device of claim 2 wherein the plurality of transistors are implemented in a stack configuration and arranged in series along a length direction between an input node and an output node.

5. The radio-frequency device of claim 4 wherein the non-uniform distribution is a function of the length direction.

6. The radio-frequency device of claim 5 wherein the non-uniform distribution includes a maximum average thickness associated with the first transistor adjacent the input node.

7. The radio-frequency device of claim 6 wherein the non-uniform distribution further includes a generally decreasing average thickness values such that the last transistor from the input node has a minimum average thickness value.

8. The radio-frequency device of claim 6 wherein the non-uniform distribution further includes a minimum average thickness value at a transistor that is between the first and last transistors from the input node.

9. The radio-frequency device of claim 2 wherein the plurality of transistors are implemented in a switch having a plurality of stacks, each stack having some of the plurality of transistors.

10. The radio-frequency device of claim 9 wherein the non-uniform distribution includes different average insulator thickness values among the plurality of stacks.

11. The radio-frequency device of claim 1 wherein the plurality of transistors are implemented over the handle wafer having a non-uniform distribution of resistivity.

12. The radio-frequency device of claim 11 wherein the non-uniform distribution of resistivity of the handle wafer is selected to adjust radio-frequency performance of some or all of the transistors.

13. A method for fabricating a radio-frequency device, the method comprising:
providing or forming a silicon-on-insulator substrate that includes an insulator layer and a handle wafer; and
forming a plurality of field-effect transistors over the insulator layer, such that each transistor is separated from the handle wafer by a corresponding portion of the insulator layer, the corresponding portion of the insulator layer having an average thickness value such that the average thickness values associated with the plurality of transistors form a non-uniform distribution.

14. The method of claim 13 wherein the insulator layer includes a buried oxide layer.

15. The method of claim 14 wherein the forming of the plurality of transistors includes forming a stack configuration such that the transistors are arranged in series along a length direction between an input node and an output node.

16. The method of claim 15 wherein the non-uniform distribution is a function of the length direction.

17. The method of claim 16 wherein the non-uniform distribution includes a maximum average thickness associated with the first transistor adjacent the input node.

18. The method of claim 17 wherein the non-uniform distribution further includes a generally decreasing average thickness values such that the last transistor from the input node has a minimum average thickness value.

19. The method of claim 17 wherein the non-uniform distribution further includes a minimum average thickness value at a transistor that is between the first and last transistors from the input node.

20. (canceled)

21. (canceled)

22. A radio-frequency module comprising:
a packaging substrate configured to receive a plurality of devices; and
a switching device mounted on the packaging substrate, the switching device including a silicon-on-insulator substrate having an insulator layer and a handle wafer, the switching device further including a plurality of field-effect transistors implemented over the insulator layer, each transistor separated from handle wafer by a corresponding portion of the insulator layer, the corresponding portion of the insulator layer having an average thickness value such that the average thickness values associated with the plurality of transistors form a non-uniform distribution.

23. (canceled)

24. (canceled)

25. (canceled)

26. (canceled)

27. (canceled)
